(19) United States
(12) Patent Application Publication
(10) Pub. No.: US 2010/0219532 A1
(43) Pub. Date: Sep. 2, 2010

(54) SEMICONDUCTOR DEVICE

(76) Inventors: Kenji Yamasaki, Osaka (JP); Yutaka Yamada, Osaka (JP); Ayako Morita, Osaka (JP); Yukiko Matsumoto, Osaka (JP)

Correspondence Address: MCDERMOTT WILL & EMERY LLP, 600 13TH STREET, NW, WASHINGTON, DC, 20005-3096, US

(21) Appl. No.: 12/160,387

(22) PCT Filed: Dec. 21, 2007
(86) PCT No.: PCT/JP2007/074710

§ 371 Date: Jul. 9, 2008

(51) Int. Cl. H01L 23/48

(52) U.S. Cl. 257/773; 257/E23.01

(57) ABSTRACT

A semiconductor device includes: a first semiconductor chip having an upper face on which at least one first electrode pad is formed; a second semiconductor chip provided above the first semiconductor chip and having an upper face on which at least one second electrode pad is formed; a conductive film external to the first semiconductor chip and the second semiconductor chip; and a wire. The wire electrically connects the first electrode pad and the second electrode pad to each other via the conductive film.

### TECHNICAL FIELD

The present invention relates to a semiconductor device provided with, for example, a plurality of semiconductor chips.

### BACKGROUND ART

A conventional semiconductor device provided with a plurality of semiconductor chips will be described with reference to FIG. 8. FIG. 8 is a perspective view illustrating a structure of the conventional semiconductor device. As illustrated in FIG. 8, the conventional semiconductor device includes: a first semiconductor chip 106 having an upper face on which first electrode pads 105 are formed; and a second semiconductor chip 107 having an upper face on which second electrode pads 104 are formed. In electrically interconnecting the semiconductor chips with the first semiconductor chip 106 stacked above the second semiconductor chip 107, the electrode pads on the upper faces of the semiconductor chips are directly connected to each other via wires 103. (see, for example, Patent Document 1)

### Patent Document 1: Japanese Unexamined Patent Publication No. 2001-185676

### DISCLOSURE OF INVENTION

### Problems That the Invention is To Solve

In the conventional semiconductor device, however, if the distance 101 between adjacent electrode pads or the distance 102 between two connected electrode pads on the respective semiconductor chips is small, processes such as bump formation and wire bonding need to be carried out at the same time in a small space in assembly for connecting the electrode pads by wires. Therefore, connection failures between adjacent wires and between adjacent bumps occur or the bumps themselves tend to be formed inadequately. These failures cause a decrease of the yield in assembly.

In addition, if the distance between adjacent electrode pads is sufficiently large and the electrode pads are directly connected to each other, wires are partially connected so that defects may arise in packaging the semiconductor device with a resin or other materials. Specifically, there are two types of regions, i.e., regions where wires are present and regions where wires are absent. Therefore, in encapsulating the semiconductor device by pouring, for example, a resin, the flow rate of the resin varies between the regions so that wires might suffer stress to be deformed. This causes formation failures of wires such as contact between adjacent wires.

The present invention has been made to solve the problems described above. An object of the present invention is to provide a highly-reliable semiconductor device which is fabricated with high yield and in which failures occurring in wire bonding of a plurality of semiconductor chips is suppressed.

### Means of Solving the Problems

To solve the problems described above, a first semiconductor device of the present invention includes: a first semiconductor chip having an upper face on which at least one first electrode pad is formed; a second semiconductor chip provided above the first semiconductor chip and having an upper face on which at least one second electrode pad is formed; a conductive film external to the first semiconductor chip and the second semiconductor chip; and a wire connecting the first electrode pad and the second electrode pad to each other via the conductive film.

In this structure, the first electrode pad and the second electrode pad are not directly connected to each other by the wire and the first semiconductor chip and the second semiconductor chip are electrically connected to each other via the conductive film. Since the conductive film is external to the first and second electrode pads, processes such as wire bonding are carried out in a wider space than that in the case of directly connecting the first electrode pad and the second electrode pad to each other. As a result, the structure of the semiconductor device of the present invention makes it possible to fabricate a semiconductor device in which occurrence of failures such as connection failures between adjacent wires is suppressed with high yield.

The first semiconductor device of the present invention may further include a resin layer encapsulating the first semiconductor chip, the second semiconductor chip, the conductive film and the wire. With this structure, since the conductive film is located within the resin layer, erroneous input of a given signal to the conductive film is prevented, so that occurrence of a short circuit at the conductive film is suppressed. Accordingly, in addition to the advantages described above, a highly-reliable semiconductor device is fabricated.

The conductive film is preferably a first lead. Then, leads not connected to external terminals, for example, are used so that a semiconductor device for which a decrease of the yield is suppressed is relatively easily fabricated without the need of additional terminals.

The first semiconductor device of the present invention may further include: a fourth lead external to the first semiconductor chip and the second semiconductor chip: and an insulating layer provided on the fourth lead. The conductive film may be formed on the insulating film.

In this structure, the first semiconductor chip and the second semiconductor chip are connected to each other via the conductive film provided above the fourth lead and the conductive film is isolated from the fourth lead by the insulating layer. If the semiconductor chips are connected to each other via the fourth lead, erroneous input of a given signal to the fourth lead might cause a short circuit. However, in the first semiconductor device of the present invention with the structure described above, since the insulating layer is sandwiched between the conductive film and the fourth lead, occurrence of a short circuit is avoided even upon input of a given signal to the fourth lead. As a result, a further highly-reliable semiconductor device is fabricated with high yield.

A second semiconductor device of the present invention includes: a first semiconductor chip having an upper face on which at least one first electrode pad is formed; a second semiconductor chip provided above the first semiconductor chip and having an upper face on which at least one second electrode pad is formed; a plurality of leads external to the first semiconductor chip and the second semiconductor chip; wires connected to the respective leads; and a resin layer encapsulating the first semiconductor chip, the second semiconductor chip, the leads and the wires, wherein each of the leads is connected to at least one of the first and second electrode pads via one of the wires.

In this structure, all the leads are connected to the semiconductor chips via the wires. Therefore, in forming a resin layer by pouring a resin into the semiconductor device, application of stress from the poured resin to the wires is suppressed so that failures such as contact between adjacent wires are prevented, as compared to a conventional semiconductor device in which wires connecting semiconductor chips and leads are locally formed. Accordingly, with the structure of the second semiconductor device of the present invention, a highly-reliable semiconductor device in which failures such as formation failures of wires are suppressed is fabricated with high yield.

### Effects of the Invention

With the structure of the semiconductor device of the present invention, a plurality of semiconductor chips are relatively easily wire-bonded. This enables a highly-reliable semiconductor device provided with a plurality of semiconductor chips to be fabricated with a decrease of the yield suppressed even under miniaturization.

### BRIEF DESCRIPTION OF DRAWINGS

FIG. 1 is a view illustrating a structure of a semiconductor device according to a first embodiment of the present invention.

FIG. 2(a) is a view illustrating an example of a conventional semiconductor device. FIG. 2(b) is a view illustrating a structure of a semiconductor device according to a second embodiment of the present invention.

FIG. 3(a) is a view illustrating a semiconductor device according to a third embodiment of the present invention. FIG. 3(b) is a cross-sectional view taken along the line IIIb-IIIb in FIG. 3(a).

FIG. 4 is a view illustrating a structure of a semiconductor device according to a fourth embodiment of the present invention.

FIG. 5(a) is a view illustrating an example of a conventional semiconductor device. FIGS. 5(b) and 5(c) are views illustrating structures of semiconductor devices according to a fifth embodiment of the present invention.

FIG. 6(a) is a view illustrating a reference example for a semiconductor device according to the present invention. FIG. 6(b) is a view illustrating a structure of a semiconductor device according to a sixth embodiment of the present invention.

FIG. 7(a) is a view illustrating an example of a conventional semiconductor device. FIG. 7(b) is a view illustrating a structure of a semiconductor device according to a seventh embodiment of the present invention. FIG. 7(c) is a view illustrating a drawback of the conventional semiconductor device.

FIG. 8 is a perspective view illustrating a structure of a conventional semiconductor device.

### DESCRIPTION OF NUMERALS

21 second semiconductor chip

22 first semiconductor chip

23a, 23b wires

24 leads

25 space

26 second electrode pad

27 first electrode pad

35 resin

41 second semiconductor chip

42 first semiconductor chip

43a first wires

43b second wires

44 leads

46 second electrode pad

47 first electrode pad

201 wires

203 leads

204 first electrode pad

205 second electrode pad

206 second semiconductor chip

207 first semiconductor chip

301 distance between adjacent electrode pads

303 wires

304 first electrode pad

305 second electrode pad

306 second semiconductor chip

307 first semiconductor chip

401 wires

403 leads

404 first electrode pad

405 second electrode pad

406 second semiconductor chip

407 first semiconductor chip

501 second semiconductor chip

502 first semiconductor chip

504 wires

505 leads

506 insulating layer

507 metal layer

508 second electrode pad

509 first electrode pad

801 second semiconductor chip

802 first semiconductor chip

803, 803a, 803b wires

804 leads

806 second electrode pad

807 first electrode pad

904 leads

1001 second semiconductor chip

1002 first semiconductor chip

1003a, 1003b wires

1004a first leads

1004b second leads

1006 second electrode pad

1007 first electrode pad

1101 second semiconductor chip

1102 first semiconductor chip

1103 wires

1104a first leads

1104b second leads

1104c, 1104d third leads

1106 wires

1007 second electrode pad

1008 first electrode pad

1109 wires

### BEST MODE FOR CARRYING OUT THE INVENTION

Hereinafter, the present invention will be described with reference to the drawings.

### Embodiment 1

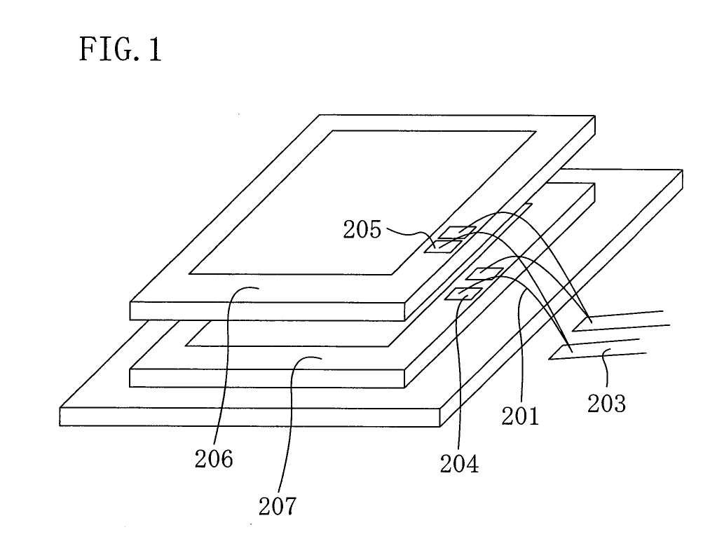

FIG. 1 is a view illustrating a structure of a semiconductor device according to a first embodiment of the present invention. As illustrated in FIG. 1, the semiconductor device of this embodiment includes: a first semiconductor chip 207 having an upper face on which a plurality of first electrode pads 204 are formed; a second semiconductor chip 206 provided above the first semiconductor chip 207 and having an upper face on which a plurality of second electrode pads 205 are formed; vacant leads (conductive film) 203 external to the first semiconductor chip 207 and the second semiconductor chip 206; and wires 201 connecting the first electrode pads 204 and the second electrode pads 205 to each other via the vacant leads 203.

A feature of the semiconductor device of this embodiment is that the first electrode pads 204 and the second electrode pads 205 are not directly connected to each other by wires and, instead, the first semiconductor chip 207 and the second semiconductor chip 206 are electrically connected to each other via the vacant leads 203. In this structure, the vacant leads 203 are external to the first semiconductor chip 207 and the second semiconductor chip 206 so that processes such as wire bonding are carried out in a wider space than that in the case of directly connecting the first electrode pads 204 and the second electrode pads 205. As a result, occurrence of failures such as connection failures between adjacent wires is suppressed, thus enabling a semiconductor device to be fabricated with high yield.

Among vacant leads provided to connect, for example, the semiconductor chips to external circuits, vacant leads which are not connected to external circuits are used as the vacant leads 203. This makes it possible to relatively easily fabricate a semiconductor device without the need of additional leads, while suppressing a decrease of the yield.

In fabricating the semiconductor device of this embodiment, the first semiconductor chip 207 and the second semiconductor chip 206 are mounted on a lead frame in this order, and then the first electrode pads 204 and the vacant leads 203 are wire-bonded. Thereafter, the second electrode pads 205 and the vacant leads 203 are wire-bonded. In this manner, the semiconductor device of this embodiment is fabricated. Accordingly, the wires 201 are formed without connection failures, for example.

### Embodiment 2

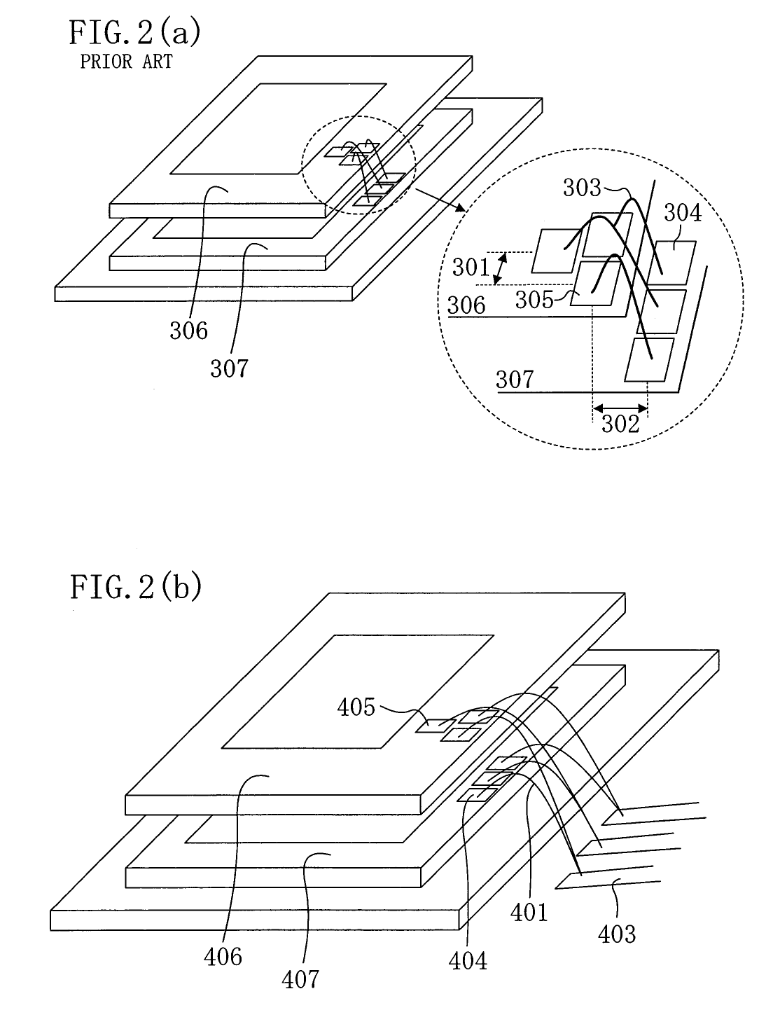

FIG. 2(a) is a view illustrating an example of a conventional semiconductor device. FIG. 2(b) is a view illustrating a structure of a semiconductor device according to a second embodiment of the present invention. First, an example of the conventional semiconductor device is briefly described with reference to FIG. 2(a).

As illustrated in FIG. 2(a), the conventional semiconductor device includes: a first semiconductor chip 307 having an upper face on which a plurality of first electrode pads 304 are formed; and a second semiconductor chip 306 having an upper face on which a plurality of second electrode pads 305 are formed. The second electrode pads 305 are arranged in, for example, two lines on an edge portion of the second semiconductor chip 306. The first electrode pads 304 and the second electrode pads 305 are directly connected to each other via wires 303.

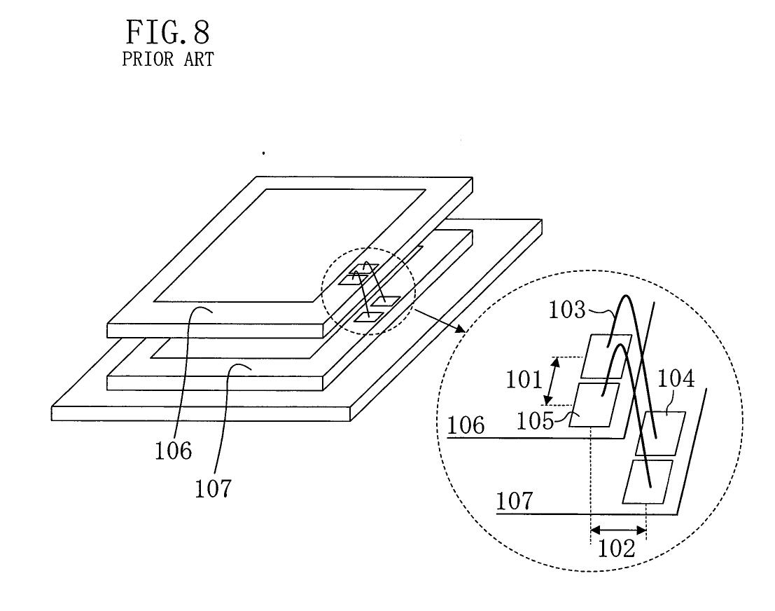

In the conventional semiconductor device with the structure described above, the second electrode pads 305 are arranged in plural lines so that the distance 301 between adjacent electrode pads is smaller than, for example, the distance 101 between adjacent electrode pads in the conventional semiconductor device illustrated in FIG. 8. Therefore, in directly connecting the first semiconductor chip 307 and the second semiconductor chip 306 by the wires 303, processes in a narrower space are needed, thus increasing the possibilities of connection failures between adjacent wires and between adjacent bumps and a failure in forming the bumps themselves.

In view of this, the present inventors devised the semiconductor device illustrated in FIG. 2(b). As illustrated in FIG. 2(b), the semiconductor device of this embodiment includes: a first semiconductor chip 407 having an upper face on which a plurality of first electrode pads 404 are formed; a second semiconductor chip 406 provided above the first semiconductor chip 407 and having an upper face on which a plurality of second electrode pads 405 are formed; vacant leads 403 external to the first semiconductor chip 407 and the second semiconductor chip 406; and wires 401 connecting the first electrode pads 404 and the second electrode pads 405 to each other via the vacant leads 403.

A feature of the semiconductor device of this embodiment is that the vacant leads 403 are provided to connect the first semiconductor chip 407 and the second semiconductor chip 406 to each other, as in the semiconductor device of the first embodiment. In this structure, the vacant leads 403 are external to the first semiconductor chip 407 and the second semiconductor chip 406 so that the processes such as wire bonding are performed smoothly. Accordingly, even in a structure in which the second electrode pads 405 are arranged in plural lines as in the semiconductor device of this embodiment, occurrence of connection failures between adjacent wires and a failure in forming the bumps is suppressed, thus enabling fabrication of a semiconductor device with high yield.

### Embodiment 3

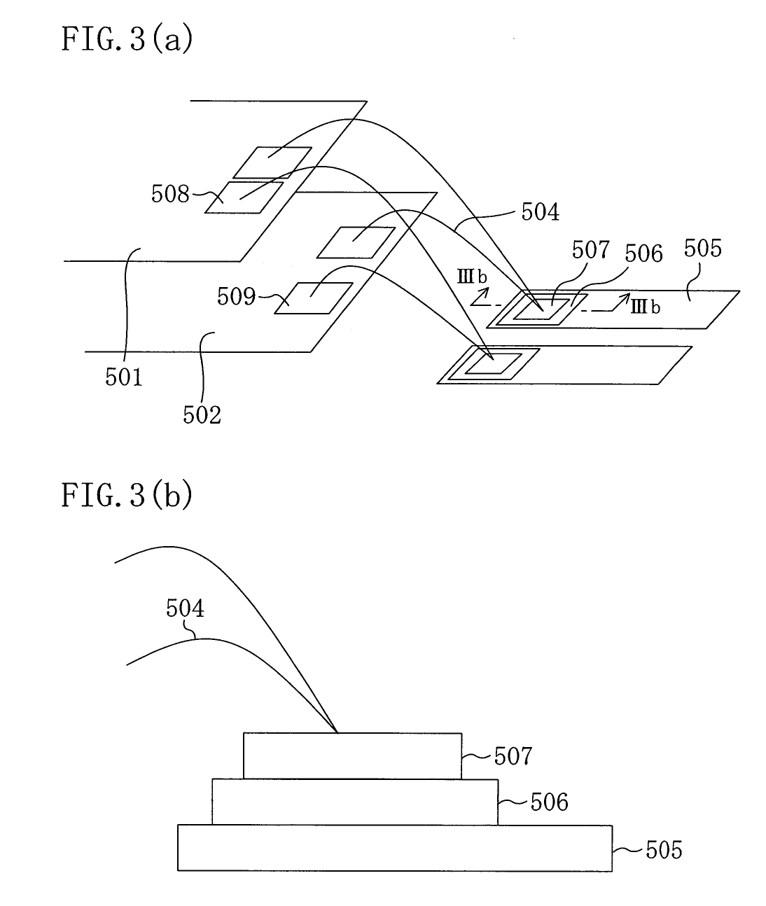

FIG. 3(a) is a view illustrating a semiconductor device according to a third embodiment of the present invention. FIG. 3(b) is a cross-sectional view taken along the line IIIb-IIIb in FIG. 3(a).

As illustrated in FIG. 3(a), the semiconductor device of this embodiment includes: a first semiconductor chip 502 having an upper face on which a plurality of first electrode pads 509 are formed; a second semiconductor chip 501 provided above the first semiconductor chip 502 and having an upper face on which a plurality of second electrode pads 508 are formed; vacant leads 505 external to the first semiconductor chip 502 and the second semiconductor chip 501; an insulating layer 506 provided on the vacant leads 505 and made of, for example, ceramic; a metal layer 507 provided on the insulating layer 506 and made of, for example, aluminum; and wires 504 connecting the first electrode pads 509 and the second electrode pads 508 to each other via the metal layer 507.

A feature of the semiconductor device of this embodiment is that the first semiconductor chip 502 and the second semiconductor chip 501 are electrically connected to each other via the metal layer 507 on the vacant leads 505. In addition, as illustrated in FIG. 3(b), the metal layer 507 and the vacant leads 505 are isolated from each other by the insulating layer 506. If the first electrode pads 509 and the second electrode pads 508 are electrically connected to each other via, for example, the vacant leads 505 and a given signal is erroneously input to the vacant leads 505, the vacant leads 505 receives the given signal and a signal from the electrode pad and, thereby, a short circuit might occur. On the other hand, in the semiconductor device of this embodiment, the insulating layer 506 sandwiched between the metal layer 507 and the vacant leads 505 prevents a short circuit from occurring even when a given signal is input to the vacant leads 505. As in the semiconductor device of the first embodiment, the metal layer 507 external to the first semiconductor chip 502 and the second semiconductor chip 501 eases processes such as wire bonding. Accordingly, with the structure of the semiconductor device of this embodiment, a highly-reliable semiconductor device is fabricated with high yield.

### Embodiment 4

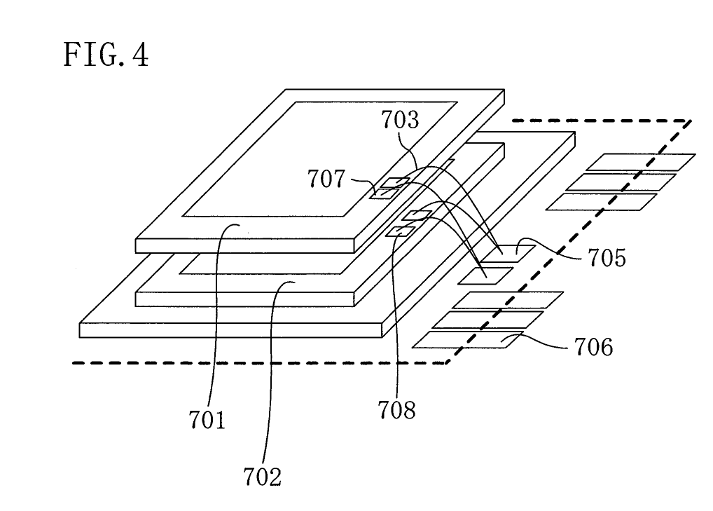

FIG. 4 is a cross-sectional view illustrating a structure of a semiconductor device according to a fourth embodiment of the present invention. As illustrated in FIG. 4, the semiconductor device of this embodiment includes: a first semiconductor chip 702 having an upper face on which a plurality of first electrode pads 708 are formed; a second semiconductor chip 701 provided above the first semiconductor chip 702 and having an upper face on which a plurality of second electrode pads 707 are formed; metal plates 705 external to the first semiconductor chip 702 and the second semiconductor chip 701; wires 703 electrically connecting the first semiconductor chip 702 and the second semiconductor chip 701 to each other via the metal plates 705; and a plurality of leads 706 provided at both sides of the metal plates 705. Though not shown, a resin layer covering the first semiconductor chip 702, the second semiconductor chip 701, the metal plates 705, the wires 703 and the leads 706 is also formed. Part of the leads 706 project from the resin layer.

A feature of the semiconductor device of this embodiment is that the metal plates 705 connecting the first semiconductor chip 702 and the second semiconductor chip 701 to each other are provided in addition to the leads 706 and are located within the resin layer. In this structure, since the metal plates 705 are located within the package, an erroneous input of a given signal to the metal plates 705 is prevented, thus avoiding a short circuit. This enables a further highly-reliable semiconductor device to be fabricated with high yield.

For the semiconductor device of this embodiment, small outline package (SOP) and a quad flat package (QFP), for example, may be used as a specific type of a package. However, the type of the package is not limited to these packages.

### Embodiment 5

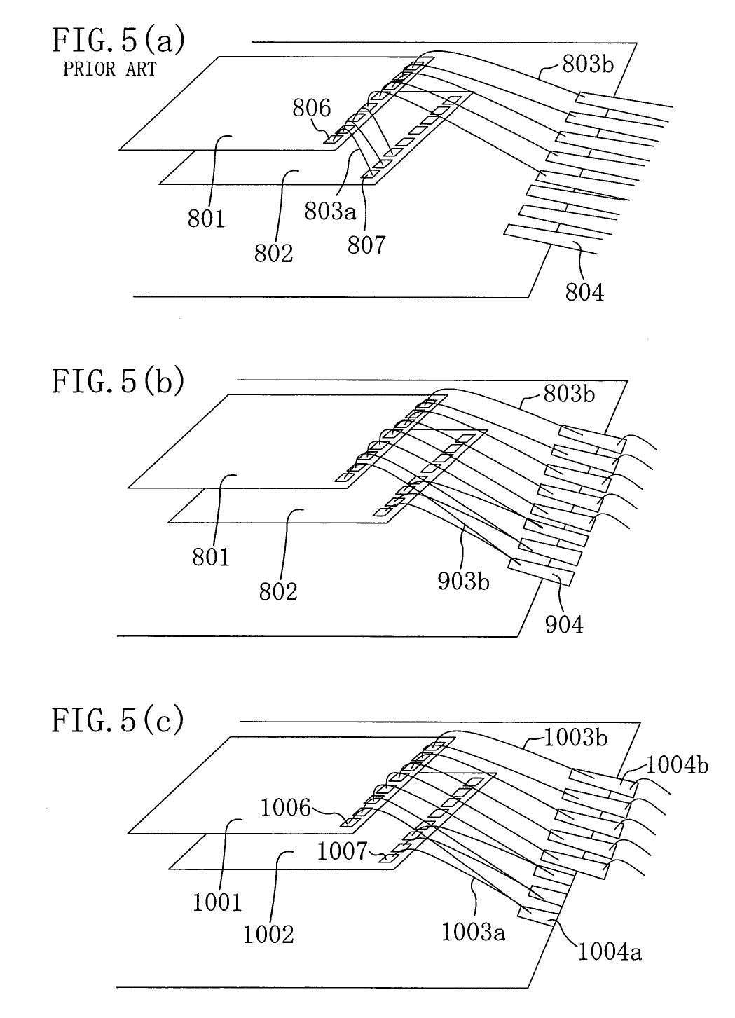

FIG. 5(a) is a view illustrating an example of a conventional semiconductor device. FIGS. 5(b) and 5(c) are views illustrating structures of semiconductor devices according to a fifth embodiment of the present invention. First, an example of the conventional semiconductor device is briefly described with reference to FIG. 5(a).

As illustrated in FIG. 5(a), the conventional semiconductor device includes: a first semiconductor chip 802 having an upper face on which a plurality of first electrode pads 807 are formed; a second semiconductor chip 801 provided above the first semiconductor chip 802 and having an upper face on which a plurality of second electrode pads 806 are formed; leads 804 external to the first semiconductor chip 802 and the second semiconductor chip 801; wires 803a connecting the first electrode pads 807 and the second electrode pads 806 to each other; and wires 803b connecting the second electrode pads 806 and the leads 804 to each other. The first semiconductor chip 802, the second semiconductor chip 801, the wires 803a and 803b and the leads 804 are encapsulated by a resin layer. Part of the leads 804 project from the resin layer. The second electrode pads 806 are connected to external circuits via the leads 804.

In the conventional semiconductor device with the structure described above, if the distance between adjacent second electrode pads 806 is small, workability in processes such as wire bonding is poor and the yield might decrease, as in the case of the conventional semiconductor device illustrated in FIG. 8. In view of this, in the semiconductor device of this embodiment, as illustrated in FIG. 5(b), the first electrode pads 807 and the second electrode pads 806 are connected to each other via vacant leads 904 that are not connected to external circuits. However, in the semiconductor device illustrated in FIG. 5(b), part of the vacant leads 904 project from the resin layer so that this part might be erroneously connected to external circuits. To prevent this, a semiconductor device of this embodiment illustrated in FIG. 5(c) is devised.

As illustrated in FIG. 5(c), the semiconductor device of this embodiment includes: a first semiconductor chip 1002 having an upper face on which a plurality of first electrode pads 1007 are formed; a second semiconductor chip 1001 provided above the first semiconductor chip 1002 and having an upper face on which a plurality of second electrode pads 1006 are formed; first leads 1004a and second leads 1004b external to the first semiconductor chip 1002 and the second semiconductor chip 1001; wires 1003a connecting the first electrode pads 1007 and the second electrode pads 1006 to each other via the first leads 1004a; and wires 1003b connecting the second electrode pads 1006 and the second leads 1004b to each other. The first semiconductor chip 1002, the second semiconductor chip 1001, the wires 1003a and 1003b, the first leads 1004a and the second leads 1004b are encapsulated by a resin layer (not shown). Part of the second leads 1004b project from the resin layer. The second electrode pads 1006 are connected to external circuits via the second leads 1004b.

A feature of the semiconductor device of this embodiment is that the first electrode pads 1007 and the second electrode pads 1006 are connected to each other via the first leads 1004a which are located within the resin layer. In this structure, since the first leads 1004a are formed within the package, input of signals from external circuits to the first leads 1004a is prevented. This avoids a short circuit caused by input of signals from the electrode pads and external circuits to the first leads 1004a. Accordingly, with the structure of the semiconductor device of this embodiment, processes such as wire bonding are relatively easily performed and a further highly-reliable semiconductor device is fabricated with high yield.

### Embodiment 6

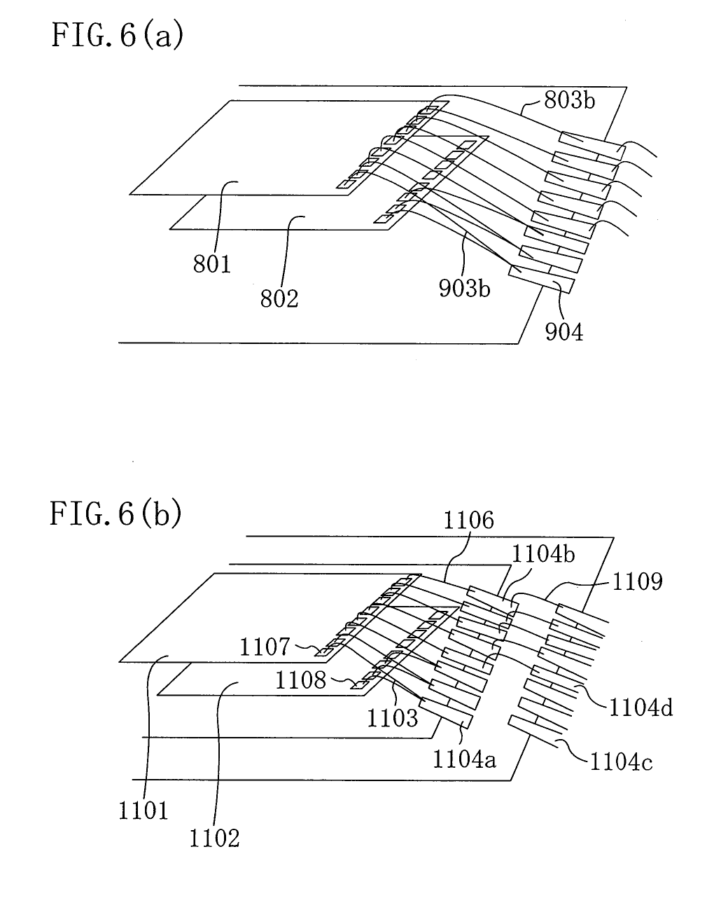

FIG. 6(a) is a view illustrating a reference example for a semiconductor device according to a sixth embodiment of the present invention. FIG. 6(b) is a cross-sectional view illustrating a structure of the semiconductor device of the sixth embodiment. The structure illustrated in FIG. 6(a) is similar to that illustrated in FIG. 5(b) and thus description thereof is herein omitted. In the semiconductor device illustrated in FIG. 6(a), part of the vacant leads 904 project from the resin layer and, therefore, might be erroneously connected to external circuits. In view of this, the semiconductor device of this embodiment illustrated in FIG. 6(b) is devised.

As illustrated in FIG. 6(b), the semiconductor device of this embodiment includes: a first semiconductor chip 1102 having an upper face on which a plurality of first electrode pads 1108 are formed; a second semiconductor chip 1101 provided above the first semiconductor chip 1102 and having an upper face on which a plurality of second electrode pads 1107 are formed; first leads 1104a and second leads 1104b external to the first semiconductor chip 1102 and the second semiconductor chip 1101; wires 1103 electrically connecting the first electrode pads 1108 and the second electrode pads 1107 to each other via the first leads 1104a; third leads 1104c and 1104d external to the first leads 1104a and the second leads 1104b; wires 1106 connecting the second electrode pads 1107 and the second leads 1104b to each other; and wires 1109 connecting the second leads 1104b and the third leads 1104d to each other. The second electrode pads 1107 are connected to external circuits through the second leads 1104b and the third leads 1104d. The first semiconductor chip 1102, the second semiconductor chip 1101, the first leads 1104a, the second leads 1104b, the wires 1103, 1106 and 1109 and the third leads 1104c and 1104d are encapsulated by a resin layer (not shown). Part of the third leads 1104c and 1104d project from the resin layer.

A feature of the semiconductor device of this embodiment is that the first semiconductor chip 1102 and the second semiconductor chip 1101 are electrically connected to each other via the first leads 1104a which are located within the resin layer. In this structure, since the first leads 1104a are located within the package, input of signals from external circuits to the first leads 1104a is avoided. This prevents a short circuit from occurring when signals are input from the electrode pads or external circuits to the first leads 1104a. Accordingly, with the structure of the semiconductor device of this embodiment, failures such as a failure in forming wires are suppressed and a further highly-reliable semiconductor device is fabricated with high yield.

### Embodiment 7

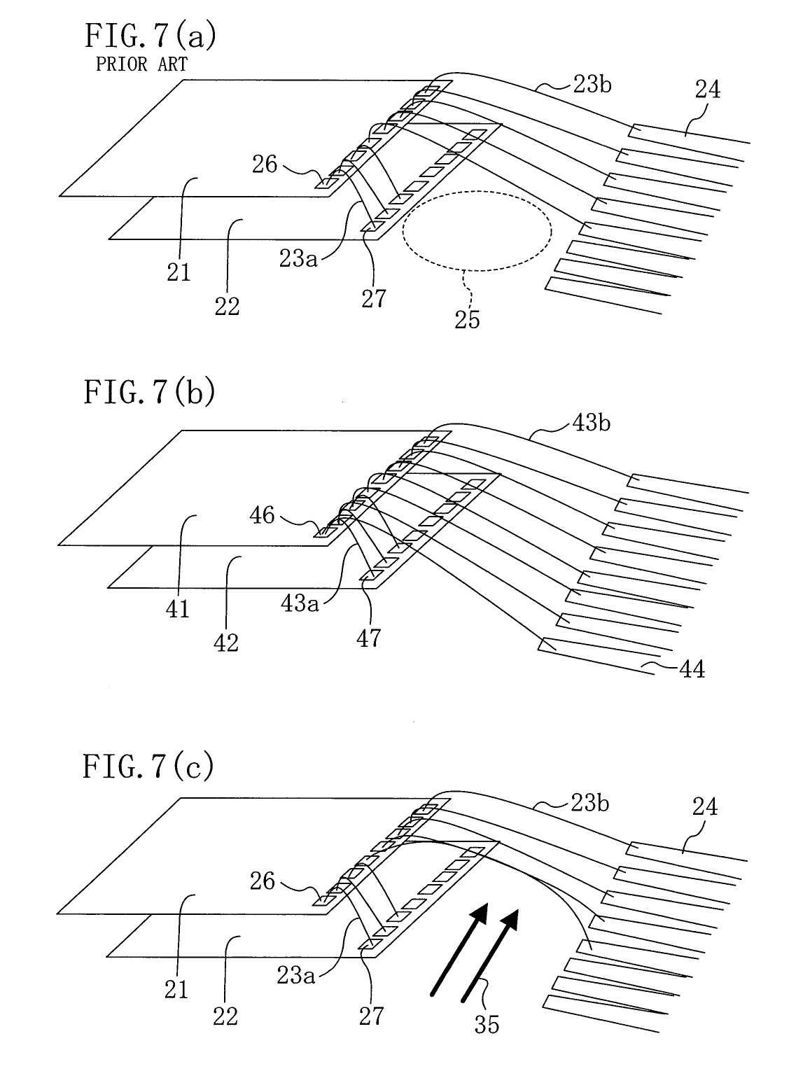

FIG. 7(a) is a view illustrating an example of a conventional semiconductor device. FIG. 7(b) is a view illustrating a structure of a semiconductor device according to a seventh embodiment of the present invention. FIG. 7(c) is a view illustrating a drawback of the conventional semiconductor device.

As illustrated in FIG. 7(a), the conventional semiconductor device includes: a first semiconductor chip 22 having an upper face on which a plurality of first electrode pads 27 are formed; a second semiconductor chip 21 having an upper face on which a plurality of second electrode pads 26 are formed; wires 23a directly connecting the first electrode pads 27 and the second electrode pads 26 to each other; leads 24 connecting the second electrode pads 26 to external circuits; and wires 23b connecting the leads 24 and the second electrode pads 26 to each other.

In the conventional semiconductor device with the structure described above, the first electrode pads 27 and the second electrode pads 26 are directly connected to each other so that some of the leads 24 are not connected to the semiconductor chips and a space 25 where no wires are provided arises. Therefore, as illustrated in FIG. 7(c), in encapsulating the semiconductor device by pouring a resin 35, for example, when the resin 35 is poured from the space 25 where no wires are present into a region where the wires 23b are present, the resin 35 flows strongly in the space 25. As a result, the wires 23b suffer stress from the resin 35 so that adjacent wires 23b might be in contact with each other. To solve such a problem, the present inventors devised the semiconductor device illustrated in FIG. 7(b).

As illustrated in FIG. 7(b), the semiconductor device includes: a first semiconductor chip 42 having an upper face on which a plurality of first electrode pads 47 are formed; a second semiconductor chip 41 provided above the first semiconductor chip 42 and having an upper face on which a plurality of second electrode pads 46 are formed; a plurality of leads 44 external to the first semiconductor chip 42 and the second semiconductor chip 41; first wires 43a connecting the first electrode pads 47 and the second electrode pads 46 to each other; and second wires 43b connecting the second electrode pads 46 and the leads 44 to each other. Though not shown, the first semiconductor chip 42, the second semiconductor chip 41, the first wires 43a, the second wires 43b and the leads 44 are encapsulated by a resin layer.

A feature of the semiconductor device of this embodiment is that all the leads 44 for connecting the semiconductor chips to external circuits are connected to the semiconductor chips via the second wires 43b. This structure suppresses variation of the flow rate of the poured resin and prevents failures such as contact between adjacent wires in packaging the semiconductor device by resin molding or other processes, as compared to a conventional semiconductor device in which wires connecting semiconductor chips and leads to each other are partially formed. As a result, with the structure of the semiconductor device of this embodiment, failures such as formation failures of wires are suppressed and a highly-reliable semiconductor device is fabricated with high yield.

### INDUSTRIAL APPLICABILITY

A semiconductor device according to the present invention is useful in reducing the size of a semiconductor device provided with, for example, a plurality of semiconductor chips.

1. A semiconductor device, comprising:
a first semiconductor chip having an upper face on which at least one first electrode pad is formed;
a second semiconductor chip provided above the first semiconductor chip and having an upper face on which at least one second electrode pad is formed;
a conductive film external to the first semiconductor chip and the second semiconductor chip; and
a wire connecting the first electrode pad and the second electrode pad to each other via the conductive film.

2. The semiconductor device of claim 1, wherein a plurality of said first electrode pads are formed on the first semiconductor chip,
a plurality of said second electrode pads are formed on the second semiconductor chip,
the first electrode pads are arranged in a plurality of lines on an edge portion of the first semiconductor chip, and
the second electrode pads are arranged in a plurality of lines on an edge portion of the second semiconductor chip.

3. The semiconductor device of claim 1, further comprising a resin layer encapsulating the first semiconductor chip, the second semiconductor chip, the conductive film and the wire.

4. The semiconductor device of claim 3, wherein the conductive film is a first lead.

5. The semiconductor device of claim 4, further comprising a second lead external to the first semiconductor chip and the second semiconductor chip, the second lead connecting one of the first and second electrode pads to an external circuit,
wherein the first lead is located within the resin layer.

6. The semiconductor device of claim 4, further comprising:
a second lead external to the first semiconductor chip and the second semiconductor chip, the second lead connecting one of the first and second electrode pads to an external circuit; and
a third lead sandwiched between the second lead and an associated one of the first and second electrode pads, located within the resin layer and connecting said one of the first and second electrode pads to the external circuit via the second lead,
wherein the first lead is located within the resin layer.

7. The semiconductor device of claim 1, further comprising:
a fourth lead external to the first semiconductor chip and the second semiconductor chip: and
an insulating layer provided on the fourth lead,
wherein the conductive film is formed on the insulating film.

8. A semiconductor device, comprising:
a first semiconductor chip having an upper face on which at least one first electrode pad is formed;
a second semiconductor chip provided above the first semiconductor chip and having an upper face on which at least one second electrode pad is formed;
a plurality of leads external to the first semiconductor chip and the second semiconductor chip;
wires connected to the respective leads; and
a resin layer encapsulating the first semiconductor chip, the second semiconductor chip, the leads and the wires,
wherein each of the leads is connected to at least one of the first and second electrode pads via one of the wires.
